(19) United States
(12) Patent Application Publication
(10) Pub. No.: US 2006/0160030 A1
(43) Pub. Date: Jul. 20, 2006

(54) Single polisilicon emitter bipolar junction transistor processing technique using cumulative photo resist application and patterning

(76) Inventors: Steve M. Leibiger, Falmouth, ME (US); Laurence M. Szendrei, Gray, ME (US); Mark A. Doyle, Lyman, ME (US)

Correspondence Address: CESARI AND MCKENNA, LLP, 88 BLACK FALCON AVENUE, BOSTON, MA, 02210, US

(21) Appl. No.: 11/384,669

(22) Filed: Mar. 20, 2006

Related U.S. Application Data
(62) Division of application No. 10/395,499, filed on Mar. 24, 2003, now Pat. No. 7,018,778.

(51) Int. Cl. G03F 7/00

(52) U.S. Cl. 430/312

(57) ABSTRACT

A process for forming a bipolar transistor where the doping implantation of the extrinsic base regions does not affect the emitter doping levels. The techniques is to not remove the photoresist layer used to defme the poly emitter contact. The photoresist layer for defining the extrinsic base regions overlays the photoresist layer over the emitter poly. When the base photoresist is processed to expose the base regions the photoresist over the emitter poly remains in tact. In this arrangement the base implantation is prevented from driving through the emitter poly and affecting the doping levels in the emitter.

### CROSS-REFERENCE TO RELATED APPLICATIONS

The present application is a continuation/divisional application of commonly assigned co-pending U.S. patent application Ser. No. 10/395,499 which was filed on Mar. 24, 2003, and which will issue on Mar. 28, 2006, and which is of common inventorship and title, and such application is hereby incorporated herein by reference.

The present application claims the benefit of U.S. Provisional Patent Application Serial No. 60/369,263, which was filed on Apr. 02, 2002, of common inventorship, title and ownership as the present application, and which provisional application is hereby incorporated herein by reference.

### BACKGROUND OF THE INVENTION

1. Field of the Invention

The present invention relates to processing of single polysilicon bipolar junction transistors, and more particularly to the use of cumulative photoresist application patterning.

2. Background Information

For a standard single polysilicon (poly) bipolar junction transistor processing flow, the emitter poly is defined using photoresist and etched using industry standard methods. The emitter definition photoresist is stripped prior to the application and patterning of the extrinsic base implant photoresist. This approach uses the already defined poly emitter (rather than non-self-aligned extrinsic base masking photoresist) to self align the extrinsic base implant to the intrinsic transistor. As a result of this, the poly emitter is doped with the extrinsic base implant. Because this implant is a lower dose than the emitter implant, it does not change the doping type of the emitter, even though it is of the opposite doping type.

FIGS. 1A and 1B show a simplified processing sequence for this prior art. FIG. 1A shows the single poly transistor emitter stack just after the emitter poly has been etched. FIG. 1B shows the same transistor during the subsequent extrinsic base implant step. This step is required to reduce the external component of the base resistance and also to later allow the formation of ohmic base contacts. Notice that the emitter poly 2 is used to block the implant 6 from the intrinsic regions of the device. This is good in that it self-aligns the intrinsic and extrinsic parts of the BJT, but bad in that the emitter poly receives the implant.

By definition, the emitter and the bases of a bipolar transistor are of different doping polarities. So, in an NPN transistor, the emitter is doped n-type (possibly with arsenic) and the base p-type (probably with boron). Therefore, during the extrinsic base implant shown in FIG. 1B, the emitter poly will be counter doped with the base doping type. During the final anneal step the unwanted p-type dopant in the emitter poly is driven into the single crystal silicon below along with the intended emitter dopant. This contamination reduces the transistor current gain (beta) by lowering the resultant emitter doping at the base-emitter junction. Other transistor characteristics are also negatively impacted. To some extent, these effects can be mitigated by good device engineering, but they can never be entirely eliminated.

Even if device adjustments are made for the unwanted dopant in the emitter polysilicon, this prior art self-alignment method has other limitations. The most obvious is a constraint on the minimum emitter poly thickness, since this layer must be at least thick enough to block the extrinsic base implant. Without this constraint, the device design might choose to make the emitter poly thinner to better optimize the transistor.

The present invention is directed to the above and other limitations of the prior art.

### SUMMARY OF THE INVENTION

The above limitations are addressed in the present invention by retaining the emitter poly defmition photoresist layer during the subsequent extrinsic base implant. This photoresist is cured with ultra-violet light in a preferred embodiment, and the base photoresist is layered over the surface of the transistor. The base regions are exposed, developed, and base dopant implanted. In this arrangement the base dopant is prevented by the cured emitter definition photoresist from penetrating the emitter region and thereby adversely affecting the transistor characteristics, or constraining the emitter polysilicon thickness, as previously described.

### BRIEF DESCRIPTION OF THE DRAWINGS

The invention description below refers to the accompanying drawings, of which:

FIGS. IA and lB are simplified flow cross sectional diagram of the prior art process flow; and

FIGS. 2A and 2B are simplified cross sectional diagrams illustrating the process flow of the present invention; and

FIGS. 3A, 3B, and 3C are more detailed cross sectional process flow diagrams showing the integration of the present invention into a single polysilicon quasi-self-aligned (QSA) emitter process flow.

### DETAILED DESCRIPTION OF AN ILLUSTRATIVE

### EMBODIMENT

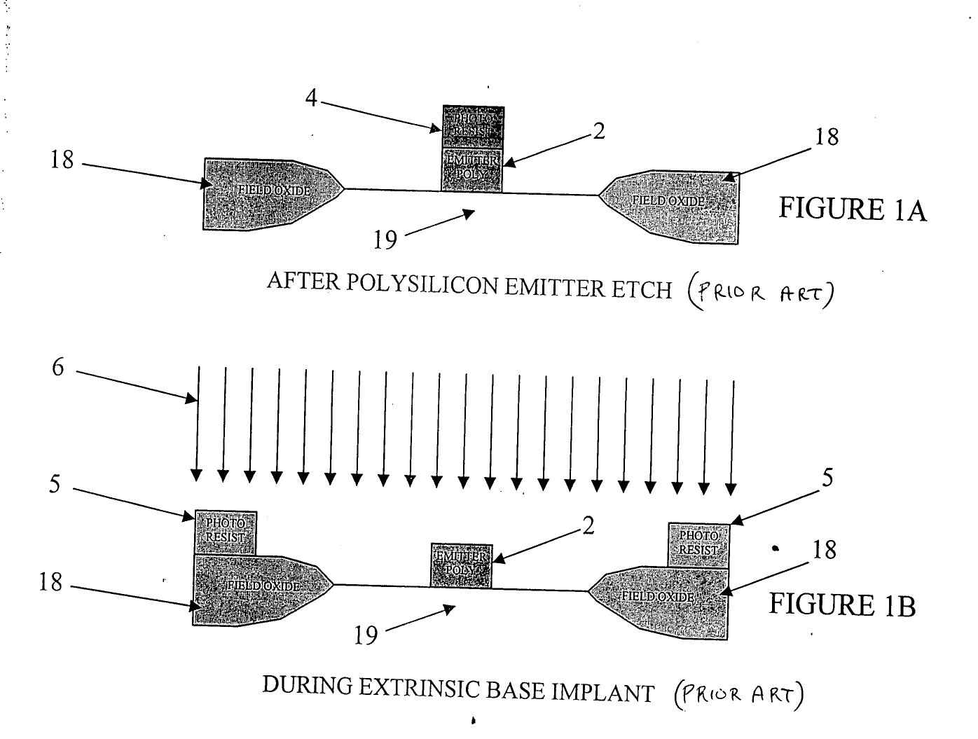

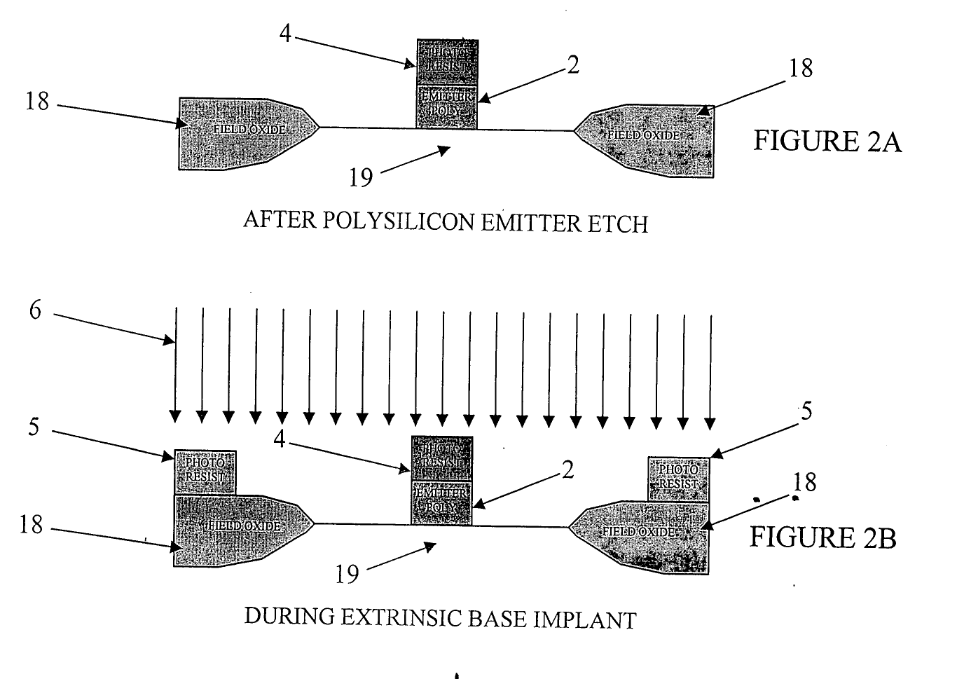

FIG. 2A shows the transistor after the emitter poly is etched leaving the same emitter poly 2 and photoresist 4 as in FIG. 1A. However, FIG. 2B shows that the photresist 4 remains over the emitter poly while the base implant is formed. After the poly pattern is defined in photoresist and etched, the photoresist is not removed. The extrinsic base implant masking photoresist is spun on the wafer, exposed, and developed. After these steps the wafer is patterned with photoresist that is a composite of the original poly definition photoresist and the additional extrinsic base definition photoresist. This is possible because the photoresist on the emitter poly is developed and ultra violet (UV) cured, and thus not affected by the subsequent exposure and development of the extrinsic base implant masking photoresist. The resulting transistor current gain is not degradated since there is no counter doping. Another benefit that springs from the base implant blocking effect on the emitter poly allows the thickness of the emitter poly to be optimized based on device performance without factoring in its ability of the emitter poly itself to block the base implant.

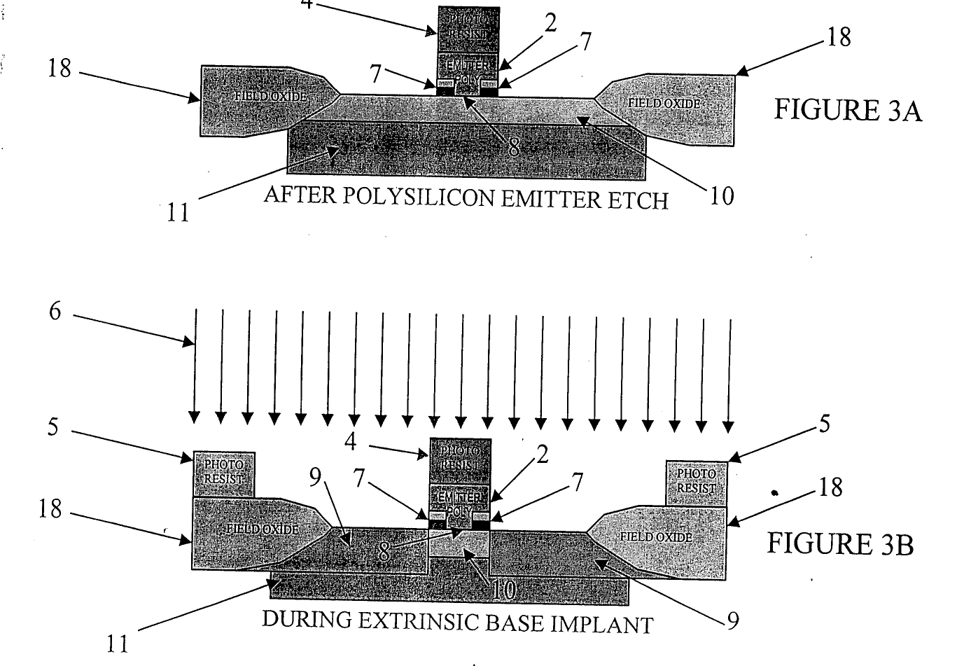

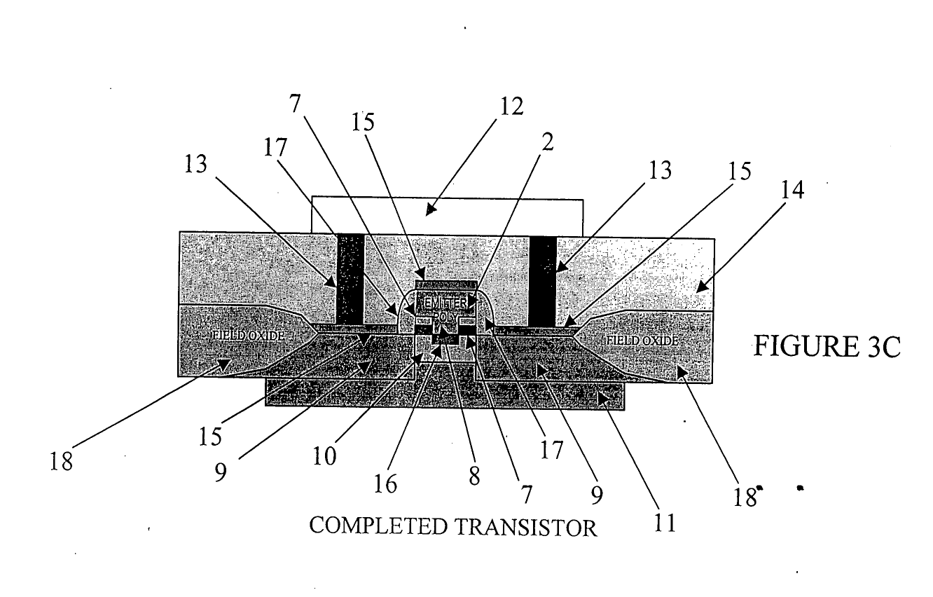

FIG. 3A shows a quasi-self-aligned (QSA) emitter bipolar transistor just after emitter polysilicon definition etch. The emitter poly 2 rests on a doped silicon base region 10, which in turn overlies a collector region 11. Lateral isolation at the surface is provided by field oxide 18, fabricated in one of several standard ways. The connection between the emitter poly 2 and the base region is defined by an opening 8 in an emitter definition stack 7 consisting of one or more thin film insulating layers. This opening is not self-aligned to the emitter poly or the active area isolation, which is the reason that this type of transistor is called quasi-self-aligned, rather than fully-self-aligned. The emitter poly is defined by photoresist 4 and etched in the normal way. FIG. 3A is conceptually the same as the prior art shown in Fig. lA up to this point.

However, in FIG. 3B, photoresist 4 is left over the emitter poly 2 when the base implant 6 is performed, in contrast to the prior art. This is done by not removing the photoresist 4 after the poly pattern is etched. Next, the extrinsic base implant masking photoresist 5 is spun on the wafer, exposed, and developed. As a result of this processing sequence, the wafer is patterned with photoresist that is a composite of the original poly definition photoresist 4 and the additional extrinsic base definition photoresist 5. This is possible because the photoresist on the emitter poly is developed and cured with ultra violet (UV) light and thus not affected by the subsequent exposure and development of the extrinsic base implant masking photoresist 5. It is evident that emitter poly 2 counter doping from the extrinsic base implant 6 of the emitter poly will not occur with this process flow. The extrinsic base implant 6 is still self-aligned to the emitter polysilicon 2, but without the unwanted counter doping inherent in the prior art. As a result, the transistor electrical characteristics are not adversely affected, and the device designer not constrained as to the thickness of the poly silicon as with the prior art. The emitter poly thickness can thus be optimized for transistor performance without consideration of its implant stopping capability.

The completed transistor cross section is illustrated in FIG. 3C. In this example, oxide spacers 17, self-aligned silicide 15, interconnect dielectric 14, contact metal plugs 13, and interconnect metal 12, are added. Note that the intrinsic transistor emitter 16 is doped by the polysilicon emitter 2, though the emitter windows 8, in the emitter definition stack 7. In the case of the present invention, this doping is not contaminated by the extrinsic base implant 6 in any way.

What is claimed is:

1. An etched bipolar transistor emitter region and an extrinsic base region self-aligned to the etched emitter region comprising:
a first photoresist layer applied on a semiconductor wafer,
a mask defining the emitter contact applied to the first photoresist layer,
means for exposing, developing, and curing the first photoresist layer using the mask to define a pattern,
means for etching the underlying emitter contact using the pattern,
a second photoresist layer applied on the surface of the semiconductor wafer,
a second mask that laterally spaces the extrinsic base implant region from the emitter region,
means for exposing and developing the second photoresist layer using,
means for implanting the extrinsic base region wherein the first and second photoresist layers block the extrinsic base implant from affecting-the emitter region.

2. The emitter and base regions of claim 1 wherein the etched emitter consists of polysilicon.

3. The emitter and base regions of claim 1 wherein the bipolar transistor is an NPN type.

4. The emitter and base regions of claim I wherein the bipolar transistor is a PNP type.

5. The emitter and base regions of claim 1 further comprising:
means for fabricating the bipolar transistor with a quasi-self-aligned architecture,
stacked insulating layers with an emitter definition window etched through them, and wherein the first photoresist layer completely encloses the emitter window.

6. The emitter and base regions of claim 1 wherein the extrinsic base implant dopant does not affect the emitter region doping.

7. An etched bipolar transistor emitter region and an extrinsic base region self-aligned to the etched emitter region comprising:
a semiconductor wafer having stacked insulating layers with an opening in the stacked insulating layers defining the emitter region;
a polysilicon layer covering the stacked insulating layers, wherein the polysilicon layer covers the emitter regions and overlaps the stacked insulating layers that surround the emitter region;
a cured photoresist layer applied covering the polysilicon layer;
an extrinsic base implant formed in the semiconductor wafer; and
wherein the extrinsic base implant is prevented from affecting the emitter region by the cured photoresist layer covering the polysilicon layer that covers the emitter region and overlaps the stacked insulating layers.

8. The emitter and base regions of claim 7 wherein the etched emitter consists of polysilicon.

9. The emitter and base regions of claim 7 wherein the bipolar transistor is an NPN type.

10. The emitter and base regions of claim 7 wherein the bipolar transistor is a PNP type.

11. The emitter and base regions of claim 7 further comprising:
means for fabricating the bipolar transistor with a quasi-self-aligned architecture,
stacked insulating layers with an emitter definition window etched through them, and wherein the first photoresist layer completely encloses the emitter window.
